(19) United States
(12) Patent Application Publication
(10) Pub. No.: US 2021/0056863 A1
(43) Pub. Date: Feb. 25, 2021

(54) HYBRID MODELS FOR DYNAMIC AGENTS IN A SIMULATION ENVIRONMENT

(71) Applicant: Samsung Electronics Co., Ltd., Suwon-si (KR)

(72) Inventor: Elena Ramona STEFANESCU, Sunnyvale, CA (US)

(21) Appl. No.: 16/576,750

(22) Filed: Sep. 19, 2019

Related U.S. Application Data
(60) Provisional application No. 62/889,033, filed on Aug. 19, 2019.

(51) Int. Cl. G09B 9/042; G09B 19/16; G06N 3/00; G06N 3/04; G06N 3/08; G05D 1/02; G05D 1/00

(52) U.S. Cl. CPC G09B 9/042; G09B 19/167; G06N 3/006; G05D 1/0088; G06N 3/088; G05D 1/0221; G06N 3/0454

(57) ABSTRACT

A system for use in an autonomous vehicle simulation is disclosed. The system may comprise a processor to execute at least two models using an input state. The system may further comprise a state mixer to mix the output states of the two models to produce a mixed output state.

### RELATED APPLICATION DATA

This application claims the benefit of U.S. Provisional Patent Application Ser. No. 62/889,033, filed Aug. 19, 2019, which is incorporated by reference herein for all purposes.

### FIELD

The inventive concepts relate generally to simulations, and more particularly to simulations involving autonomous vehicles.

### BACKGROUND

There are several different models that may be used to simulate dynamic agents in autonomous vehicle simulations (or to determine the operation of an autonomous vehicle). Different models operate well in different situations. For example, some models may work well in simple situations, such as handing lane keeping on a straight stretch of road, which are straight-forward and not computation intensive, but do poorly in complex situations, such as navigating a roundabout involving training. Other models may work well in complex situations, but handle simple situations poorly and require more computational resources. No single model exists that handles all situations involving autonomous vehicles perfectly, or even well.

A need remains to provide for a way to simulate dynamic agents and autonomous vehicles in all situations, both simple and complex.

### BRIEF DESCRIPTION OF THE DRAWINGS

FIG. 1 shows a model-based approach and a deep data driven approach each receiving an input state and producing an output state and a confidence level.

FIG. 2 shows a processor operating to simulate an actor in an interacting multiple model of an autonomous vehicle simulation, according to an embodiment of the inventive concept.

FIG. 3 shows details of a machine including the processor of FIG. 2.

FIG. 4 shows details of the world definition of a simulation.

FIG. 5 shows different models handling different types of situations in the interacting multiple model.

FIG. 6 shows a vehicle attempting to remain behind another vehicle in a simulation.

FIG. 7 shows the state mixer of FIG. 2 mixing the output states of the various models.

FIG. 8 shows the confidence mixer of FIG. 2 mixing the confidence levels of the various models.

FIG. 9 shows a weight determiner determining weights for the various models based on their confidence levels.

FIG. 10 shows the interacting multiple model feeding back for the next iteration of the simulation.

FIGS. 11A-11B show a flowchart of an example procedure for an interacting multiple model to combine outputs from multiple individual models, according to an embodiment of the inventive concept.

FIG. 12 shows a flowchart of an example procedure to set initial parameters for the interacting multiple model, according to an embodiment of the inventive concept.

FIG. 13 shows a flowchart of an example procedure to determine weights for the individual models in the interacting multiple model, according to an embodiment of the inventive concept.

### DETAILED DESCRIPTION

Reference will now be made in detail to embodiments of the inventive concept, examples of which are illustrated in the accompanying drawings. In the following detailed description, numerous specific details are set forth to enable a thorough understanding of the inventive concept. It should be understood, however, that persons having ordinary skill in the art may practice the inventive concept without these specific details. In other instances, well-known methods, procedures, components, circuits, and networks have not been described in detail so as not to unnecessarily obscure aspects of the embodiments.

It will be understood that, although the terms first, second, etc. may be used herein to describe various elements, these elements should not be limited by these terms. These terms are only used to distinguish one element from another. For example, a first module could be termed a second module, and, similarly, a second module could be termed a first module, without departing from the scope of the inventive concept.

The terminology used in the description of the inventive concept herein is for the purpose of describing particular embodiments only and is not intended to be limiting of the inventive concept. As used in the description of the inventive concept and the appended claims, the singular forms “a”, “an”, and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The components and features of the drawings are not necessarily drawn to scale.

Embodiments of the inventive concept are directed toward the ability to generate behaviors for all the dynamic agents by using different models to deal with various simulating environments. The novelty consists in part in the usage of a model-based approach (such as Intelligent Driver Model (IDM) or Minimizing Overall Braking Induced by Lane Changes (MOBIL)) with a model-free model (such as Generative Adversarial Imitation Learning (GAIL)) that are smoothly blended within the computer environment without the need of human interference or human choice. Using software flags, the computer may choose the level of situation and smoothly change back and forth between model types to match changing simulation environments. This may increase the accuracy of the simulation software, ensure better software for the driving experience, and consequently increase safety.

Autonomous vehicles are threatening to disrupt the automotive, aerospace, and industrial equipment industries with the emergence of self-driving cars. However, research in autonomous urban driving is hindered by infrastructure costs and the logical difficulties of training and testing systems in the physical world. Instrumenting and operating even one autonomous vehicle requires significant funds, and manpower. And a single vehicle is far from sufficient from collecting the requisite data that cover the multitude of corner cases that must be processes for both training and validation.

For an autonomous vehicle to be accepted and certified for widespread use, its software must be verified and validated as being as safe as or safer than a human equivalent. Simulating miles driven is the only feasible way to overcome this limitation, so companies have turned to simulation. Simulation may democratize research in autonomous urban driving. It is also necessary for system verification, since some scenarios are too dangerous to be staged in the physical world.

Digital simulation validation is a particularly difficult challenge. One needs to simulate the workings of all the technological building blocks simultaneously, incorporating the complexity of on-the-road scenarios and the behavior of other drivers. A simulator needs to be capable to simulate various scenarios, each of which may be tailored to the particular circumstances that one needs to test. There is currently no simulator that is suitable for all the functions of an autonomous vehicle.

The generation of a simulation scenario should be related to a certain driving behavior. A number of agents need to be randomly assigned around the system under test (SUT), at certain speeds and on different lanes with different driving behaviors (from passive to aggressive ones). The driver model should have some hyper-parameters within certain ranges that will map to a driving behavior. Sampling these parameters will result in different scenarios that may be scaled and easily repeated.

The driver model should be able to adjust to a variety of atmospheric conditions and illumination regime, different positions and color of the sun, intensity and color of diffuse sky radiation, ambient occlusion, atmospheric fog, cloudiness, and precipitation. Also, it should be invariant to the number and pose of the other agents, their shape, and wardrobe. The evaluation of the model should test for both driving performance as well comfort.

This patent application is directed toward the development of sophisticated intelligent behavior models for real-world traffic, which may be applied at scales for thousands of simulation scenarios. This may be done by automatically and smoothly blending the transition of model based modeling with model free models. When one wants to simulate a very complex driving situations such as: a busy intersection, unusual patterns like construction zones/road work, and busy roundabouts, using model based simulation is not going to be very accurate and will not reflect the real driving behavior. A solution for such situations is to use data collected by traffic cameras or any other type of camera deployed with the goal to capture traffic scenes. This way a model-free model may be created using only gather data which yields models of naturalistic behavior. However, this type of data is not always available or needed (for simple cases an IDM or MOBIL will perform equally well) and a mixture of models may be used with great improvements in mimicking real driver behaviors. The combination of these two types of simulations is done using an Interacting Multiple Model (IMM). The switching between models will be based on the information received from the simulation environment. At all times information regarding the simulation world (urban, rural, highway), number of lanes and road network complexity (e.g., roundabouts, intersections, construction zones etc.), traffic participation (number of dynamic vehicles, their speed and spread on different lanes), atmospheric conditions and illumination regime, different positions and color of the sun, intensity and color of diffuse sky radiation, ambient occlusion, atmospheric fog, cloudiness and precipitation, may be known through different flags.

Both models may be run concurrently, creating an algorithm-level redundancy. For instance, if high errors are returned/reported the model based system, the model free may guide the simulation and vice versa.

A model-based model has a mathematical formulation and models the actions of the dynamic agent (vehicle) such as accelerations, braking, and steering as a response to the surrounding traffic by means of acceleration strategy towards a desired speed in the free-flow regime, a braking strategy for approaching other vehicles or obstacles, a car-driving strategy for maintaining a safe distance when driving behind another vehicle, etc. The driver's behavior may be externally influenced by the simulator environmental input such as limited motorization and breaking power of the vehicle, visibility conditions, road characteristics such as horizontal curves, lane narrowing, ramps, gradients, and road traffic regulations. The IDM and MOBIL are model-based models and by changing their parameters one may change the driving style: passive, aggressive, tailgater, speeder etc. so one may generate driving behavior that matches human behavior.

In a complex scenario, the dynamic agents involved in traffic not only have to follow traffic rules but also react to unpredictable maneuvers of the other participant agents. This may lead to abrupt and constant direction and speed changes. Due to a human like interaction it is near impossible to predict and represent this changes using a simplistic mathematical model. Therefore, model-free models such as Generative Adversarial Imitation Learning (GAIL) may be used. In a model-free simulation we replace the mathematical formulation with data (recordings). Recordings may be raw video off existing cameras like traffic cameras, or from other sensors deployed for capturing traffic information. As an example, roundabouts represent a challenge for model-based models to reproduce with fidelity the behavior of different agents in such traffic situation. However, with data collected by cameras over an extended period of time one may have enough information to generate human like behavior in a roundabout.

Also, in the roundabout example the two approaches may both be used: on the straight road leading up to the roundabout a model-based approached is used, while in the roundabout a model-free technique is deployed. However, prior the roundabout and at the end of the straight road, the IMM blends the two models, resulting in a smooth transition between the two.

GAIL is based on a popular computer vision technique called Generative Adversarial Network. Since it is model-free, it requires interaction with the environment to generate a policy, but it does not need to construct a model for the environment.

Using a Generative Adversarial Imitation Learning approach, not only may behavior that has been previously observed be mimicked, but behavior may be extrapolated to other realistic behaviors which is needed for scaling up to millions of simulations scenarios.

One may start with a random noise and generate actions that fit distributions of state and actions defining the behavior. This policy may be mapped into a trajectory and sent to the discriminator with the goal to generate human-like behavior. The distribution is where the sampling actions may be obtained by minimizing the loss between the generated distribution and the data distribution.

As an exemplification of its usage, consider again the roundabout situation for which there may be weeks' worth of data. However, often the drivers that passed through the roundabout are only the inhabitants of that particular town. The benefit of using GAIL is that the model may be capable of generating pairs of action and states that mimic drivers with different behavior than the locals.

A policy is a set of sequential actions (state, action pairs) that dynamic agent needs to take to maneuver through the simulated situation. The state is the raw visual input, while the action consists of steering, acceleration, and braking. The training process of GAIL may be thought of as a generative model, which is a stochastic policy that when coupled with a fixed simulation environment, produces similar behaviors to the expert demonstrations (collected data). As a result, raw pixels (video) may be used as input and produce human-like behaviors in complex high-dimensional dynamic environments.

An Interactive Multiple Model (IMM) combines states from different models to get a better state estimate. The IMM approach is based on filter structural adaptation (model switching). The IMM algorithm carries out a soft-switching between the various model modes by adjusting the probabilities of each mode, which are used as weightings in the combined global state estimate.

Embodiments of the Inventive Concept:

1. Take different types of models (such as model-based modeling and model-free modeling) and smoothly blends then together for a better representation of behavior for a dynamic agent.

2. May be used for different types of agents, autonomous driving, bicycles, pedestrians, robots, and anything that moves.

3. Permit the blending of two completely different modeling approaches.

4. Have the capability to transition from a fairly simple situation to a more complex one.

5. Complex scenarios require no knowledge of the dynamics, it just needs lots of data.

6. Use an Interacting Multiple Model approach to transition between situations.

7. Are usable in autonomous driving vehicles for quick realization of environment and situations allowing for faster response toward transitions into, though, and out of new or unforeseen situations without human intervention.

8. Combine model-based traffic modeling with model-free approaches.

Lane Keeping Using Intelligent Driver Model (IDM)

Lane keeping may occur in simulations that are either simple or complex. Parameters include:

1. Desired speed

2. Desired time gap

3. Minimum allowed distance

4. Maximum acceleration

5. Desired deceleration

6. Maximum deceleration

7. Look ahead horizon

$${\dot{x}}_{α} = \frac{d {x}_{α}}{d t} = {v}_{α}$$

$${\dot{v}}_{α} = \frac{d {v}_{α}}{d t} = a ( 1 - {( \frac{{v}_{α}}{{v}_{0}} )}^{δ} - {( \frac{{s}^{*} ( {v}_{α} , Δ {v}_{α} )}{{s}_{α}} )}^{2} ) with$$

$${s}^{*} ( {v}_{α} , Δ {v}_{α} ) = {s}_{0} + {v}_{α} T + \frac{{v}_{α} Δ {v}_{α}}{2 \sqrt{ab}}$$

From Video to Behavior

Video may be taken of human behavior in a situation, and that video may be used to generate instructions for how a simulation might operate in that scenario.

Hybrid Models Embodiments of the inventive concept support the use of different models for different situations:

1. When on highway, use IDM.

2. When at intersection, use GAIL.

3. Following the approach used in the IMM (interacting multiple models).

The IMM will help transitioning between modes by fusing the output of the models for an overall smooth estimate.

Interactive Multiple Models

The probability of transitioning from Model i at time k−1 to Model j at time k (the transition probability) may be calculated as:

pᵢⱼ=P(Mₖ^{j}|Mₖ₋₁ⁱ)

The mixed state at time k+1 and the confidence level of the mixed state at time k+1 may be calculated as:

$${\hat{x}}_{k + 1} = {\sum }_{i = 1 , 2} {μ}_{k + 1}^{i} {\hat{x}}_{k + 1}^{i}$$

$${P}_{k + 1} = {\sum }_{i = 1.2} {μ}_{k + 1}^{i} ( {P}_{k + 1}^{i} + ( {\hat{x}}_{k + 1}^{i} - {\hat{x}}_{k + 1} ) {( {\hat{x}}_{k + 1}^{i} - {\hat{x}}_{k + 1} )}^{T} )$$

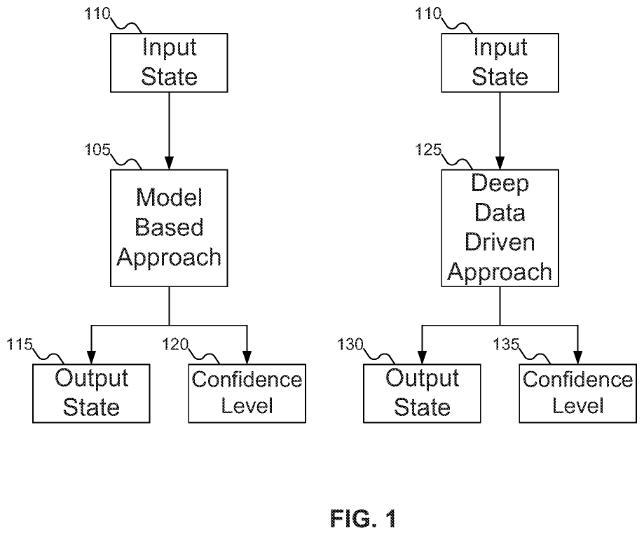

FIG. 1 shows two models, each receiving input and generating outputs, for an actor in an autonomous vehicle simulation. The actor may be an agent in the simulation (that is, for a system under test for validation, another actor whose behavior should be considered in selecting an appropriate course of action for the system under test), or the actor may be the system under test itself. In FIG. 1, model-based approach 105, which may be, for example, an Interactive Driving Model (IDM), may receive input state 110 and produce output state 115 and confidence level 120. (Throughout this document, the term “approach” is used instead of “model”, to avoid the confusing term “model-free model”. But the term “approach” is intended to encompass models, simulations, and any other similar terms.) Input state 105 may be a vector that represents various details about the state of the actor and other actors in the simulation. Examples of data that may be included in input state 105 may include the location of the actor (for example, in three dimensions, with time may be represented separately), the heading of the actor (for example, in six dimensions: both along each axis and around each axis), values for parameters relating to the actor's behavior (for example, how far the actor should be relative to other actors), and so on. Input state 110 may also include information about other actors in the simulation (perhaps all actors in the simulation or just those within a certain range of the primary actor), as well information about the simulation environment and its complexity, all of which may also be represented as vectors. Note that input state 110 may represent the data in any desired form: for example, instead of separating location and velocity information into separate elements in input state 110, the information may be combined into degrees of freedom.

Given input state 110, which represents the state of the actor and the simulation at a particular point in time, model-based approach 105 may generate output state 115. Output state 115 may represent the state of the actor at the next moment in time. Output state 115 thus represents the location, bearing, velocity, etc. of the actor at the next moment in time, and may indicate what changes are represented relative to input state 110. For example, output state 115 may indicate that the actor is slowing down over time. (A person of ordinary skill in the art will understand that states are determined at points in time that are separated by some measureable but small amount. For example, output state 115 may be considered to represent the state of the actor 0.001 seconds, or any other delta, after input state 110, rather than treating time as truly continuous.)

In a similar manner, deep data driven approach 125 may be another approach used to determine the appropriate actions for the actor in the simulation. Again, the actor in the simulation may be another actor whose behavior should be considered by the system under test, or the actor may be the system under test itself. But whereas model-based approach 105 may be IDM, deep data driven approach 125 may apply a different strategy to determine an actor's behavior. For example, deep data driven approach 125 may use Generative Adversarial Imitation Learning (GAIL). Deep data driven approach 125 may use a different approach to simulation than model-based approach 105: for example, whereas model-based approach may use mathematical equations to determine output state 115 from input state 110, deep data driven approach 125 may use a suitably programmed neural network to determine an appropriate action given the input state. As a result, output state 130 of deep data driven approach 125 may be different from output state 115 of model-based approach 105. Moreover, model-based approach 105 and deep data driven approach 125 may work well in different situations. For example, model-based approach 105 may work well in simple situations such as lane changing or lane keeping, but deep data driven approach 125 may work better in more complex situations such as intersections, roundabouts, and construction zones. Thus, while neither approach independently handles all situations well, given any situation one or the other (or both) may provide a good output.

Like model-based approach 105, deep data driven approach 125 produces output state 130, which represents the state of the actor (or the simulation as a whole) at the next moment in time.

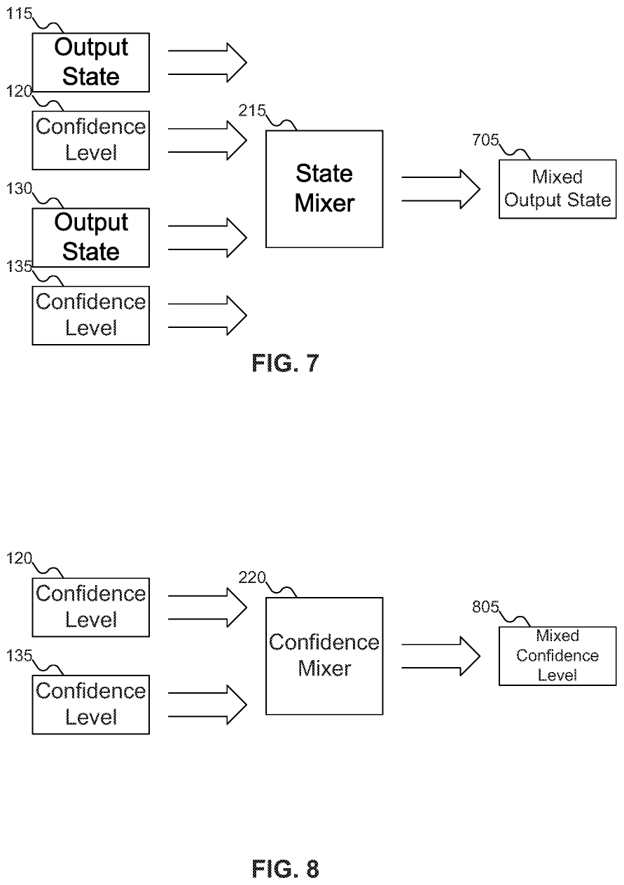

Note that FIG. 1 shows input state 110 being provided as input to both model-based approach 105 and deep data driven approach 125. This is intentional: if each approach is to provide an appropriate determination of the state at the next moment in time, both approaches should receive the same input. But it is possible that the two approaches may expect inputs that differ in some ways. For example, one approach might expect an element in input state 110 that is not needed by the other approach, the two approaches might expect the input values to be formatted in different ways (for example, separating location from velocity as opposed to using degrees of freedom, or using different units), or ordered in different ways. Not shown in FIG. 1 is an adaptor module that adapts input state 110 to the appropriate requirements of each approach: this adaptor module may reorder the entries in input state 110 (which may also involve eliminating some entries), and converting from one unit to another as appropriate. Similarly, output states 115 and 130 may provide different information. But since generally it is expected that the output state at one moment in time would be used as the input to the simulation to determine the output at the next moment in time, adapting output states 115 and 130 to feed back into input state 110 is roughly the reverse of the use of the adaptor module on input 110, and is not further described here. (Note that reordering the entries in output states 115 and 130 is simple, as is making sure that an entry used by one approach that is not needed by the other approach is placed in the correct location for input state 110. What is not as simple is how to combine values when both approaches return values in a particular entry: for example, the next location for the actor. How values are combined is discussed further with reference to FIG. 7 below.)

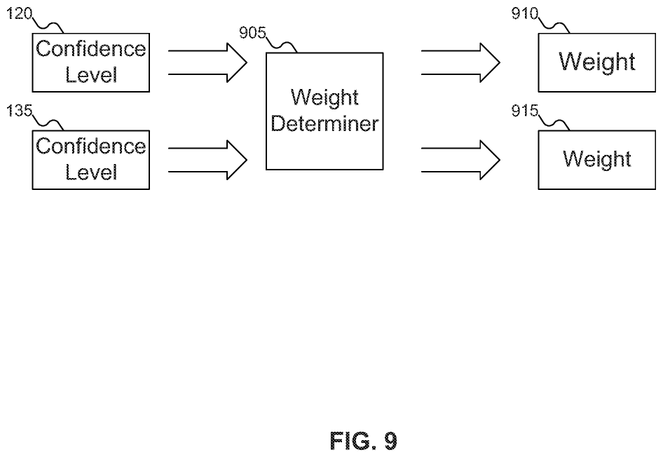

Aside from producing output states 115 and 130, model-based approach 105 and deep data driven approach 125 may also produce confidence levels 120 and 135. Confidence levels 120 and 135 may represent how confident the approaches are that output states 115 and 130, respectively, are accurate: the higher the confidence level, the more the output state is considered to be accurate. Confidence levels 120 and 135 may be just numbers along a scale (with any desired range: for example, from 0 to 100, with 0 representing no confidence and 100 representing complete confidence), or they may be more complex concepts, such as covariance matrices. Like output states 115 and 130, confidence levels 120 and 135 may be mixed: how confidence levels 120 and 135 may be mixed is discussed further with reference to FIG. 8 below.

FIG. 1 shows only two approaches being used to process input 110. But embodiments of the inventive concept may extend to more than two approaches. For example, three approaches or more may also be used, each of which may have varying strengths and weaknesses. Any reference in this document to approaches 105 and 125 (or reference to “two” approaches) should be understood as referring to all approaches supported in the embodiment of the inventive concept.

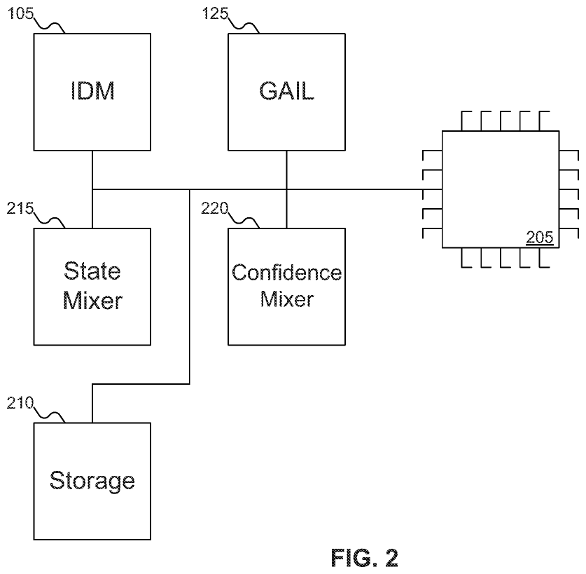

Turning to FIG. 2, approaches 105 and 125 may be implemented as software running on processor 205. Alternatively, approaches 105 and 125 may be implemented using firmware stored on another chip (not shown in FIG. 2) or may be implemented using hardware, such as a Field Programmable Gate Array (FPGA), Application-Specific Integrated Circuit (ASIC), or other hardware. While FIG. 2 shows approaches 105 and 125 being implemented using a single processor 205, embodiments of the inventive concept may implement approaches 105 and 125 using any number of processor, some of which may share approaches and others of which may be dedicated to a single approach, without limitation.

Processor 205 (and thereby approaches 105 and 125) may be implemented in various constructs, such as within a computer system or within a vehicle (if the vehicle is autonomous). Any reference in this document to “machine” is intended to represent any physical implementation of embodiments of the inventive concept, including (but not limited to) a computer implementation or within an autonomous vehicle. This computer system (or machine) may include processor 205. Processor 205 may be any variety of processor: for example, an Intel Xeon, Celeron, Itanium, or Atom processor, an AMD Opteron processor, an ARM processor, etc. While FIG. 2 shows a single processor 205, the machine may include any number of processors, each of which may be single core or multi-core processors, and may be mixed in any desired combination. The machine may also include other hardware and/or software components not shown in FIG. 2, such as a memory and an operating system. The memory may be any variety of memory, such as flash memory, Dynamic Random Access Memory (DRAM), Static Random Access Memory (SRAM), Persistent Random Access Memory, Ferroelectric Random Access Memory (FRAM), or Non-Volatile Random Access Memory (NVRAM), such as Magnetoresistive Random Access Memory (MRAM) etc. The memory may also be any desired combination of different memory types, and may be managed by a memory controller. The memory may be used to store data that may be termed “short-term”: that is, data not expected to be stored for extended periods of time. Examples of short-term data may include temporary files, data being used locally by applications (which may have been copied from other storage locations), and the like.

Processor 205 and the memory may also support an operating system under which various applications (which may include approaches 105 and 125) may be running. These applications may issue requests to read data from or write data to storage 210, which may be the memory or other storage, such as a hard disk drive or Solid State Drive (SSD). Storage 210 may be used, for example, to store initial parameters (or ranges of values for initial parameters, along with what types of behaviors the ranges of values represent) used to initialize the simulation.

The machine may also include state mixer 215 and confidence mixer 220. State mixer 215 may be used to mix output states 115 and 130 of FIG. 1 to form a mixed output state. Confidence mixer 220 may be used to mix confidence levels 120 and 135 of FIG. 1 to form a mixed confidence level. State mixer 215 and confidence mixer 220, like approaches 125 and 110, may be implemented as software running on processor 205 or on another processor (not shown in FIG. 2), may be implemented using another processor (not shown in FIG. 2), or may be implemented using an FPGA, ASIC, or other custom hardware. State mixer 215 is discussed further with reference to FIG. 7 below; confidence mixer 220 is discussed further with reference to FIG. 8 below.

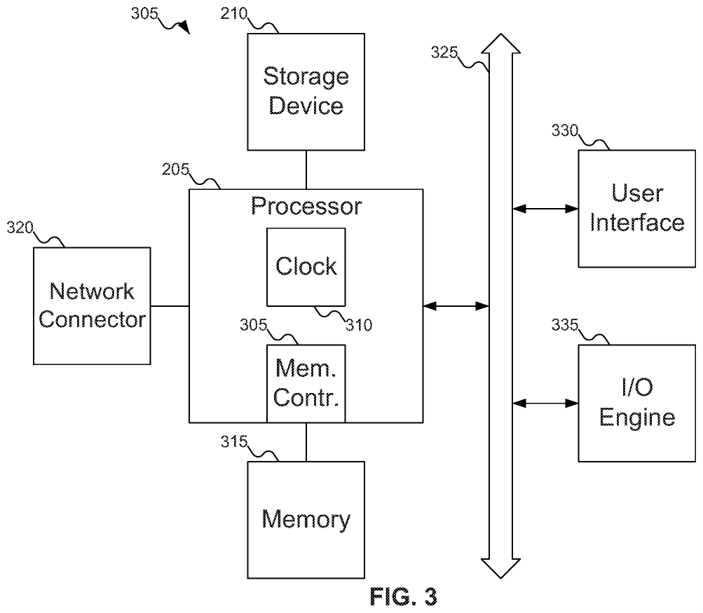

FIG. 3 shows additional details of the machine that includes processor 205 of FIG. 2. In FIG. 3, typically, the machine includes one or more processors 205, which may include memory controllers 305 and clocks 310, which may be used to coordinate the operations of the components of the machine. Processors 205 may also be coupled to memories 315, which may include random access memory (RAM), read-only memory (ROM), or other state preserving media, as examples. Processors 205 may also be coupled to storage devices 210, and to network connector 320, which may be, for example, an Ethernet connector or a wireless connector. Processors 205 may also be connected to buses 325, to which may be attached user interfaces 330 and Input/Output interface ports that may be managed using Input/Output engines 335, among other components.

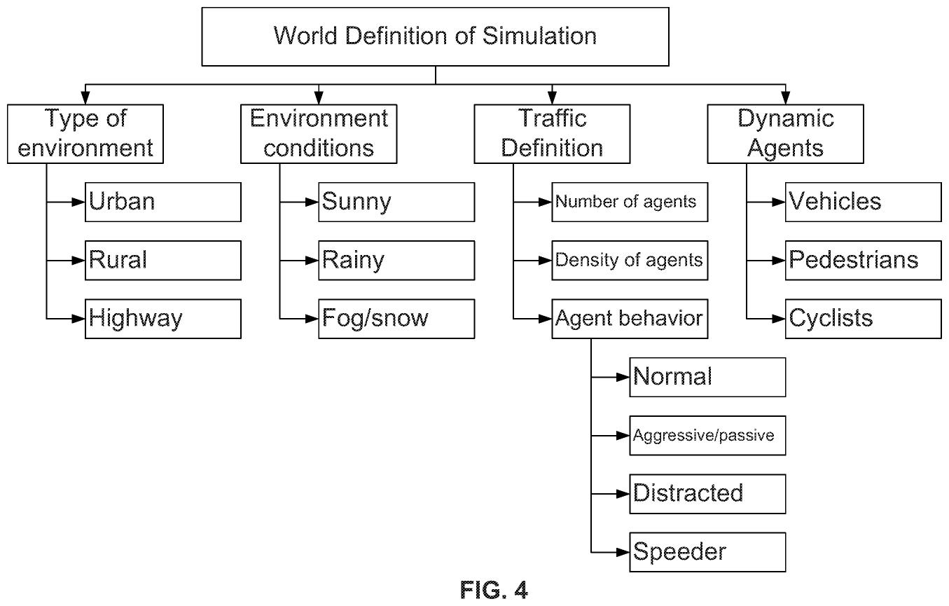

FIG. 4 shows details of the world definition of a simulation. In FIG. 4, a simulation includes many variables, such as the type of environment, the environment conditions, the traffic definition, and the dynamic agents. For example, the type of environment could be rural, urban, or highway (among others: for example, off-road). The environment conditions may include sunny conditions, rainy conditions, fog or snow, ice, etc. Further, the environment and the environment conditions may vary over time: a vehicle might transition from city driving to highway driving, and then exit the highway in a rural area, for example. Or a vehicle might start in, say, a ski area with snow flurries, that eventually transition to rain as the vehicle descends in elevation, and might eventually transition from the rainy conditions to sun as the rain clears.

The dynamic agents themselves might include other vehicles, cyclists, and pedestrians, all maneuvering in the simulation at varying speeds. The traffic definition may specify the number of these dynamic agents, their density (how many dynamic agents exist on average within a certain range of the system under test), and their behavior. Agent behavior may vary from “normal” or typical behavior to aggressive or passive behavior, agents that are distracted and less likely (or slower) to notice unexpected changes, and agents that like to travel faster than they should.

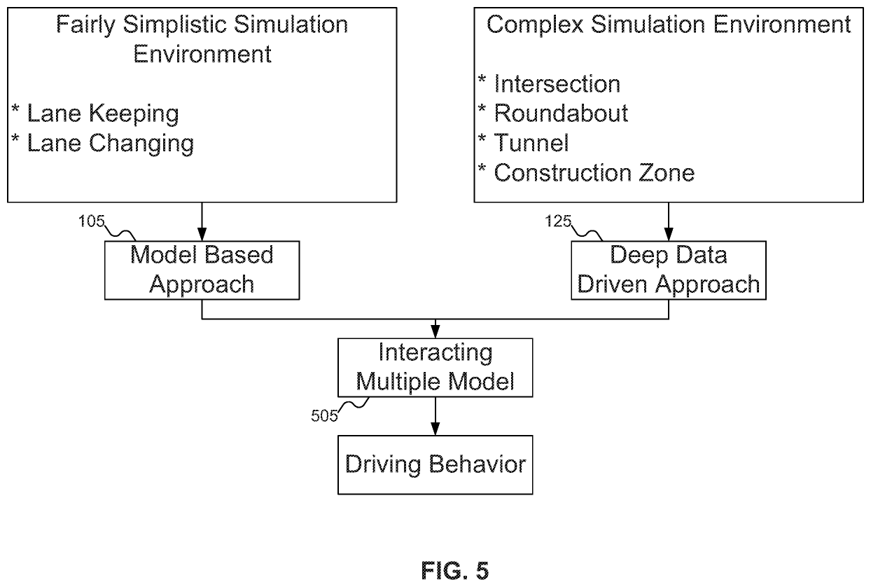

FIG. 5 shows different models handling different types of situations in the interacting multiple model. As discussed above, some simulation situations are fairly simple, such as lane keeping and lane changing, and may be handled well using model-based approach 105. On the other hand, some simulation situations are more complex, such as roundabouts, intersections, tunnels, and construction zones. For these situations model-based approach 105 is less reliable, and deep data driven approach 125 may offer a better solution. To take advantage of both models, Interacting Multiple Model (IMM) 505 may receive outputs from both model-based approach 105 and deep data driven approach 125 and combine their outputs to determine the driving behavior for an actor in the simulation.

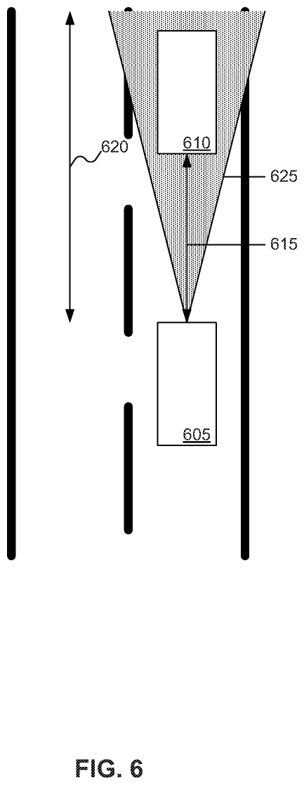

FIG. 6 shows a vehicle attempting to remain behind another vehicle in a simulation. In FIG. 6, vehicle 605 is the actor whose behavior is being managed by the simulation. Vehicle 605 is attempting to stay in the lane, but remain behind vehicle 610. The distance between vehicles 605 and 610 is shown as arrow 615, while arrow 620 represents the distance that the simulation may look ahead of vehicle 605 (also called the look ahead horizon). Given the distance that vehicle 605 may look ahead, the simulation may detect relevant data from cone 625 to use in determining the next state of the simulation.

The distance 615 between vehicles 605 and 610 may be measured using visual information. But the distance alone is not everything that is needed: it is also important to know the time gap: that is, how much time it will take vehicle 605 to overtake vehicle 610. This time gap is relevant, as it feeds back into what the speed of vehicle 605 should be to maintain the distance from vehicle 610. If the two vehicles are moving at the same speed, then vehicle 605 will never overtake vehicle 610, which is the preferred state when vehicle 605 is to stay in its lane. On the other hand, unless vehicle 610 is travelling at an excessive rate of speed, vehicle 605 also should not be travelling slower than vehicle 610 as long traffic rules (e.g., speed limit) are not violated.

If distance 615 is represented as d and the speeds of the leading and trailing vehicles (vehicles 610 and 605 respectively) are represented as v_{ego} and v_{lead}, then the time gap may be computed as

$$Time gap = \frac{d}{{v}_{ego} - {v}_{lead}} .$$

IDM 125 of FIG. 1 may use the following equations to help calculate relevant information about the actor in the simulation:

$${\dot{x}}_{α} = \frac{d {x}_{α}}{d t} = {v}_{a}$$

$${\dot{v}}_{α} = \frac{d {v}_{α}}{d t} = a ( 1 - {( \frac{{v}_{α}}{{v}_{0}} )}^{δ} - {( \frac{{s}^{*} ( {v}_{α} , Δ {v}_{α} )}{{s}_{a}} )}^{2} ) , where$$

$${s}^{*} ( {v}_{α} , Δ {v}_{α} ) = {s}_{0} + {v}_{α} T + \frac{{v}_{α} Δ {v}_{α}}{2 \sqrt{ab}} .$$

Parameters that may be factored into how these equations are used may include the desired speed of vehicle 605, the desired time gap of distance 615, the minimum allowed distance, the maximum acceleration of vehicle 605, the desired of vehicle 605, the maximum deceleration of vehicle 605, look ahead horizon 620, and others.

To achieve the mixing of output states 115 and 130 of FIG. 1 from approaches 105 and 125 of FIG. 1, IMM 505 may include various modules, such as state mixer 215 and confidence mixer 220 of FIG. 2. FIG. 7 shows state mixer 215 of FIG. 2 mixing the output states of the various models. In FIG. 7, state mixer 215 may receive output states 115 and 130, along with confidence levels 120 and 135. State mixer 215 may then combine output states 115 and 130 using the relative confidence levels 120 and 135 to produce mixed output state 705.

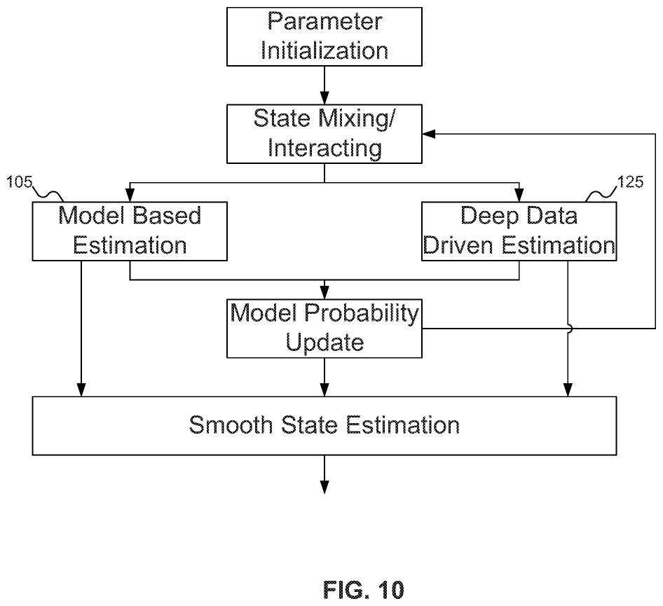

State mixer 215 may operate in a number of ways. One way in which state mixer 215 may operate is to determine weights for each of output states 115 and 130: these weights may be determined using confidence levels 120 and 135. How these weights are calculated is discussed further with reference to FIG. 9 below.

Given the weights for each approach 105 and 125 of FIG. 1, state mixer 215 may then combine output states 115 and 130 according to the weights using multiplication and addition. For example, if μₖⁱ represents the weight associated with approach i at time k, and if xₖⁱ represents the output state of approach i at time k, then state mixer 215 may produce mixed output state 705 as \hat{x}ₖ=Σᵢμₖⁱxₖⁱ, (of course, xₖⁱ may be a vector, so each component of the vector may be weighted and added correspondingly). In some embodiments of the inventive concept, the weights may range from 0 to 1, with 0 meaning that no weight is given to a particular output state and 1 meaning that full weight is given to a particular output state: in such embodiments of the inventive concept an added equation may be introduced establishing that Σᵢμₖⁱ=1. In other embodiments of the inventive concept, the weights may be assigned values that range across other limits (without bound), without normalizing the weights.

FIG. 8 shows confidence mixer 220 of FIG. 2 mixing the confidence levels of the various models. Confidence mixer 220 may operate similarly to state mixer 215 of FIG. 7, except that confidence mixer 220 operates to mix confidence levels 120 and 135 rather than output states 115 and 130, to produce mixed confidence level 805. As such, in some embodiments of the inventive concept, particularly those embodiments where confidence levels 120 and 135 are simply numeric values, confidence mixer 220 may apply equations similar to state mixer 215 of FIG. 2.

But in other embodiments of the inventive concept, confidence mixer 220 may operate slightly differently. For example, consider the situation where confidence levels 120 and 135 are covariance matrices. In such situations a simple weighting of the covariance matrices may not produce a meaningful result (or at least not an entirely meaningful result). Instead, an alternative equation may be used with confidence mixer 220, such as Pₖ=Σᵢμₖⁱ(Pₖⁱ+(xₖⁱ−\hat{x}ₖ)(xₖⁱ−\hat{x}ₖ)^{T}), where μₖⁱ represents the weight associated with approach i at time k, Pₖⁱ represents the covariance matrix for approach i at time k, xₖⁱ represents the output state of approach i at time k, \hat{x}ₖ represents mixed output state 705 of FIG. 7 at time k, and T represents the transpose operation.

In FIGS. 7 and 8, the weights μₖⁱ are mentioned but not defined. Weight determiner 905, shown in FIG. 9, explains how the weights μₖⁱ may be calculated. Given confidence levels 120 and 135, weights 910 and 915 may be calculated.

In the simplest form, where there are only two approaches (such as model-based approach 105 and deep data driven approach 125 of FIG. 1), weights 910 and 915 may be calculated directly from the relative confidence levels. That is, the higher confidence level 120 is, the higher corresponding weight 910 would be, and the lower confidence level 120 is, the lower corresponding weight 910 would be (weight 915 would be similarly related to confidence level 135). Alternatively, if the confidence levels may be expressed as a single number (which may be over any desired range: for example, from 0 to 1, with 0 indicating no confidence at all and 1 indicating absolute confidence), confidence levels 120 and 135 may be summed and weights 910 and 915 may be calculated as the relative contribution of each of confidence levels 120 and 135 to the overall sum. Such equations may be easily adapted to situations where there are three or more approaches being used in the simulation.

It is worth noting that there are situations in which approaches 105 and 125 of FIG. 1 may return no output at all. That is, there may be situations where approaches 105 and 125 of FIG. 1 may not calculate a solution. If some embodiments of the inventive concept the approach in question may return a confidence level of 0 (or some other value indicating no confidence at all in the output state). Weight determiner 905 may then automatically assign a weight of 0 (or some other appropriate value) indicating that state mixer 215 of FIG. 7 should not factor the corresponding output state into the calculation of mixed output state 705 of FIG. 7). In such situations, state mixer 215 of FIG. 7 will automatically avoid giving any weight to the output state of that approach.

In other embodiments of the inventive concept, the approach may not necessary return a confidence level indicating that there is no solution. In such embodiments of the inventive concept, weight determiner 905 may detect that the approach had no solution and may automatically assign a weight of 0 (or some other value) indicating that the output state of that approach should not factor into the calculation of mixed output state 705 of FIG. 7. In yet other embodiments of the inventive concept, detecting that the approach could not determine a solution may be determined by state mixer 215 of FIG. 7 or some other module within IMM 505 of FIG. 5.

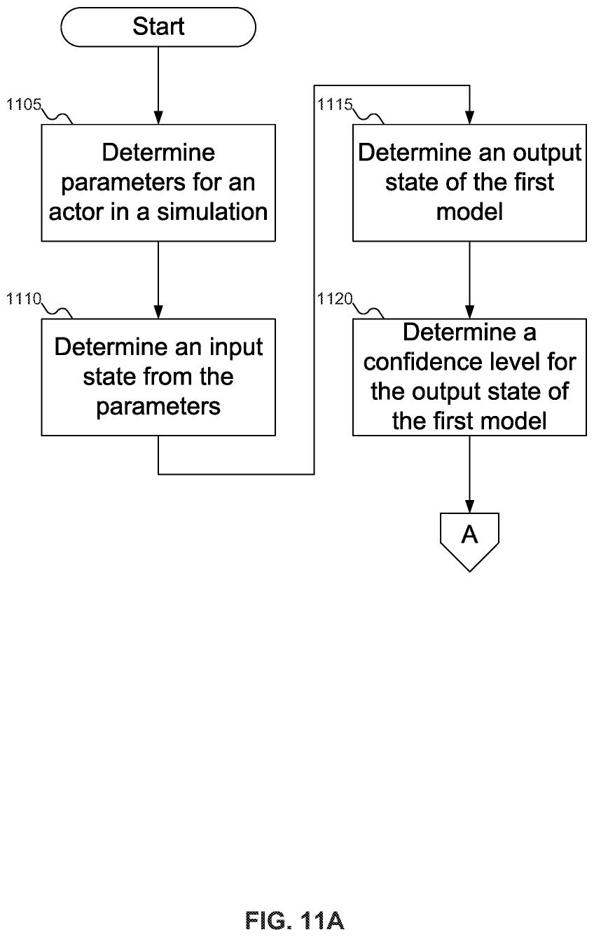

FIG. 10 shows interacting multiple model 505 of FIG. 5 feeding back for the next iteration of the simulation. FIG. 10 shows a slightly different embodiment of the inventive concept as compared with FIGS. 7-9 given the module names, but the overall operation is similar. As shown in FIG. 10, parameter initialization may be used to set the initial state of the simulation. This input state may then be provided to a state mixing/interacting module, which is responsible for providing inputs to approaches 105 and 125 (this input may be thought of as the output of state mixer 215 of FIG. 7). Approaches 105 and 125, in turn, produce output states and confidence levels that may be passed to a model probability update module (operating similarly to confidence mixer 220 of FIG. 8, weight determiner 905 of FIG. 9, or both) to determine the updated probability of the model. This information, along with the output states and confidence levels of approaches 105 and 125, may be provided to smooth state estimation (again similar to state mixer 215 of FIG. 7) to determine the new state of IMM 505 of FIG. 5; the model probability update may also be returned back to the state mixing/interacting module to determine the next input state for approaches 105 and 125.

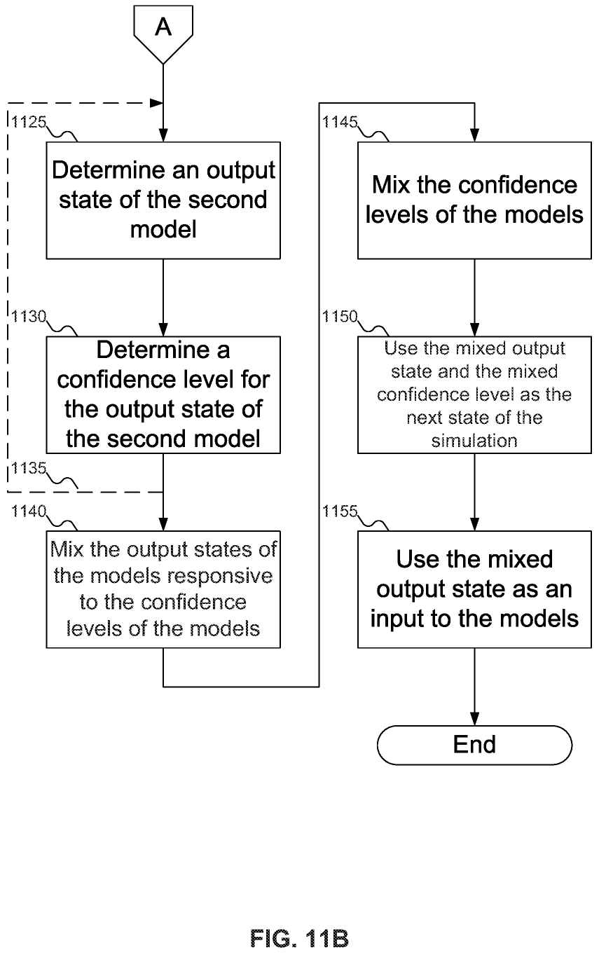

FIGS. 11A-11B show a flowchart of an example procedure for interacting multiple model 505 of FIG. 5 to combine outputs from multiple individual models, according to an embodiment of the inventive concept. In FIG. 11A, at block 1105, the initial parameters for a particular agent being modeled using IMM 505 of FIG. 5 are determined. At block 1110, the initial parameters are used to determine initial state 110 of FIG. 1 of the agent being simulated. For example, the initial parameters may define a range of acceptable values for a particular variable, such as how sharply the steering wheel is turned, or how quickly the agent accelerates/decelerates, etc.: a value from within such a range may be selected for the initial state of the agent. At block 1115, input state 110 of FIG. 1 may be provided to approach 105 of FIG. 1, to produce output state 115 of FIG. 1, and at block 1120 confidence level 120 of FIG. 1 for output state 115 of FIG. 1 may also be determined.

At block 1125 (FIG. 11B), input state 110 of FIG. 1 may also be provided to approach 125 of FIG. 1, to produce output state 130 of FIG. 1, and at block 1130 confidence level 135 of FIG. 1 for output state 130 of FIG. 1 may also be determined. Note that dashed line 1135 leads back to block 1125, in case there are more than two approaches 105 and 125 of FIG. 1 being used in the simulation.

At block 1140, state mixer 215 of FIG. 7 may mix output states 115 and 130 of FIG. 1 to produce mixed output state 705 of FIG. 7. At block 1145, confidence mixer 220 of FIG. 8 may mix confidence levels 120 and 135 of FIG. 1 to produce mixed confidence level 805 of FIG. 8. At block 1150, IMM 505 of FIG. 5 may use mixed output state 705 of FIG. 7 and mixed confidence level 805 of FIG. 8 to determine the next state of the simulation. Finally, at block 1155, mixed output state 705 of FIG. 7 may be used as the next input state to approaches 105 and 125 of FIG. 1, returning to block 1115 of FIG. 11A.

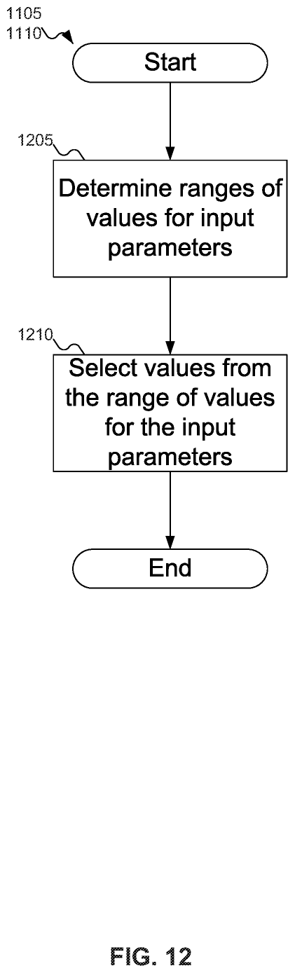

FIG. 12 shows a flowchart of an example procedure to set initial parameters for the interacting multiple model, according to an embodiment of the inventive concept. In FIG. 12, at block 1205, ranges of values for an input variable may be determined. Note that a “range” might be only a single value—that is, the lower and upper bounds of the range might be the same. But in general a range may have different lower and upper values, and might even include multiple non-contiguous ranges for a single initial parameter. Then, at block 1210, IMM 505 of FIG. 5 may select a value from the range as the initial value for that variable in input state 110 of FIG. 1.

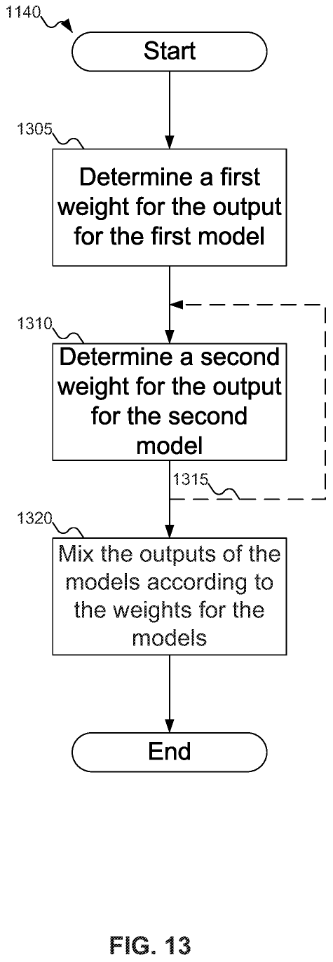

FIG. 13 shows a flowchart of an example procedure to determine weights for the individual models in the interacting multiple model, according to an embodiment of the inventive concept. In FIG. 13, at block 1305, weight determiner 905 of FIG. 9 may use confidence levels 120 and 135 of FIG. 1 to determine weight 910 of FIG. 9 for approach 125 of FIG. 1. As discussed above with reference to FIG. 9, weight determiner 905 of FIG. 9 may determine weight 910 of FIG. 9 based on the relative confidence levels 120 and 135 of FIG. 1. At block 1310, weight determiner 905 may use confidence levels 120 and 135 of FIG. 1 to determine weight 915 of FIG. 9 for approach 110 of FIG. 1. Dashed arrow 1315 indicates that block 1310 may be repeated if there are more than two approaches 105 and 125 of FIG. 1. Finally, at block 1320, weights 910 and 915 of FIG. 9 may be used to mix output states 115 and 130 of FIG. 1.

In FIGS. 11A-13, some embodiments of the inventive concept are shown. But a person skilled in the art will recognize that other embodiments of the inventive concept are also possible, by changing the order of the blocks, by omitting blocks, or by including links not shown in the drawings. All such variations of the flowcharts are considered to be embodiments of the inventive concept, whether expressly described or not.

Embodiments of the inventive concept offer technical advantages over the prior art. In conventional systems data is moved to the host processor for processing: where the amount of data to be processed is large, this data movement imposes a load on data transmission resources between the storage device and the host processor. This data movement also imposes a processing load on the host processor. In contrast, embodiments of the inventive concept permit processing to occur locally to storage, eliminating both the data transfer load and freeing host processing resources. In addition, the data movement interconnect is scalable, permitting more nodes to be easily added to support additional local processing without introducing significant additional expenses in terms of equipment purchase or operation.

The following discussion is intended to provide a brief, general description of a suitable machine or machines in which certain aspects of the inventive concept may be implemented. The machine or machines may be controlled, at least in part, by input from conventional input devices, such as keyboards, mice, etc., as well as by directives received from another machine, interaction with a virtual reality (VR) environment, biometric feedback, or other input signal. As used herein, the term “machine” is intended to broadly encompass a single machine, a virtual machine, or a system of communicatively coupled machines, virtual machines, or devices operating together. Exemplary machines include computing devices such as personal computers, workstations, servers, portable computers, handheld devices, telephones, tablets, etc., as well as transportation devices, such as private or public transportation, e.g., automobiles, trains, cabs, etc.

The machine or machines may include embedded controllers, such as programmable or non-programmable logic devices or arrays, Application Specific Integrated Circuits (ASICs), embedded computers, smart cards, and the like. The machine or machines may utilize one or more connections to one or more remote machines, such as through a network interface, modem, or other communicative coupling. Machines may be interconnected by way of a physical and/or logical network, such as an intranet, the Internet, local area networks, wide area networks, etc. One skilled in the art will appreciate that network communication may utilize various wired and/or wireless short range or long range carriers and protocols, including radio frequency (RF), satellite, microwave, Institute of Electrical and Electronics Engineers (IEEE) 802.11, Bluetooth®, optical, infrared, cable, laser, etc.

Embodiments of the present inventive concept may be described by reference to or in conjunction with associated data including functions, procedures, data structures, application programs, etc. which when accessed by a machine results in the machine performing tasks or defining abstract data types or low-level hardware contexts. Associated data may be stored in, for example, the volatile and/or non-volatile memory, e.g., RAM, ROM, etc., or in other storage devices and their associated storage media, including hard-drives, floppy-disks, optical storage, tapes, flash memory, memory sticks, digital video disks, biological storage, etc. Associated data may be delivered over transmission environments, including the physical and/or logical network, in the form of packets, serial data, parallel data, propagated signals, etc., and may be used in a compressed or encrypted format. Associated data may be used in a distributed environment, and stored locally and/or remotely for machine access.

Embodiments of the inventive concept may include a tangible, non-transitory machine-readable medium comprising instructions executable by one or more processors, the instructions comprising instructions to perform the elements of the inventive concepts as described herein.

The various operations of methods described above may be performed by any suitable means capable of performing the operations, such as various hardware and/or software component(s), circuits, and/or module(s). The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or steps of a method or algorithm and functions described in connection with the embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Having described and illustrated the principles of the inventive concept with reference to illustrated embodiments, it will be recognized that the illustrated embodiments may be modified in arrangement and detail without departing from such principles, and may be combined in any desired manner. And, although the foregoing discussion has focused on particular embodiments, other configurations are contemplated. In particular, even though expressions such as “according to an embodiment of the inventive concept” or the like are used herein, these phrases are meant to generally reference embodiment possibilities, and are not intended to limit the inventive concept to particular embodiment configurations. As used herein, these terms may reference the same or different embodiments that are combinable into other embodiments.

The foregoing illustrative embodiments are not to be construed as limiting the inventive concept thereof. Although a few embodiments have been described, those skilled in the art will readily appreciate that many modifications are possible to those embodiments without materially departing from the novel teachings and advantages of the present disclosure. Accordingly, all such modifications are intended to be included within the scope of this inventive concept as defined in the claims.

Embodiments of the inventive concept may extend to the following statements, without limitation:

Statement 1. An embodiment of the inventive concept includes a system, comprising:

a processor executing at least a first model to produce a first output state for an input state for an autonomous vehicle simulation and a second model to produce a second output state for the input state for the autonomous vehicle simulation; and

a state mixer to mix the first output state and the second output state to produce a mixed output state,

wherein the mixed output state represents an actor in the autonomous vehicle simulation.

Statement 2. An embodiment of the inventive concept includes the system according to statement 1, wherein the actor includes one of a dynamic agent in the autonomous vehicle simulation or an autonomous vehicle in the autonomous vehicle simulation.

Statement 3. An embodiment of the inventive concept includes the system according to statement 1, wherein:

the processor is operative to produce a first confidence level for the first output state for the first model and a second confidence level for the second output state for the second model; and

the state mixer is operative to mix the first output state and the second output state to produce a mixed output state responsive to the first confidence level and the second confidence level.

Statement 4. An embodiment of the inventive concept includes the system according to statement 3, wherein:

the first confidence level includes a first covariance matrix; and

the second confidence level includes a second covariance matrix.

Statement 5. An embodiment of the inventive concept includes the system according to statement 3, further comprising a confidence mixer to mix the first confidence level and the second confidence level to produce a mixed confidence level.

Statement 6. An embodiment of the inventive concept includes the system according to statement 3, wherein:

the state determiner includes a weight determiner to determine a first weight and a second weight responsive to the first confidence level and the second confidence level; and

the state mixer is operative to weight the first output state with the first weight and the second output state with the second weight to produce the mixed output state.

Statement 7. An embodiment of the inventive concept includes the system according to statement 6, wherein:

the processor is operative to execute at least a third model to produce a third output state for the input state for an autonomous vehicle simulation and a third confidence level for the third output state for the third model;

the weight determiner is operative to determine the first weight, the second weight, and a third weight responsive to the first confidence level, the second confidence level, and the third confidence level; and

the state mixer is operative to weight the first output state with the first weight, the second output state with the second weight, and the third output state with the third weight to produce the mixed output state.

Statement 8. An embodiment of the inventive concept includes the system according to statement 1, further comprising storage for at least one initial parameter.

Statement 9. An embodiment of the inventive concept includes the system according to statement 8, wherein the storage for at least one initial parameter includes storage for at least one range of values for the at least one parameter responsive to a desired agent behavior.

Statement 10. An embodiment of the inventive concept includes the system according to statement 1, wherein the mixed output state may be used as a second input for the first model and the second model.

Statement 11. An embodiment of the inventive concept includes the system according to statement 1, wherein:

the first model includes a model-based approach; and

the second model includes a deep data driven approach.

Statement 12. An embodiment of the inventive concept includes the system according to statement 11, wherein:

the model-based approach includes an Intelligent Driver Model (IDM); and

the deep data driven approach includes a Generative Adversarial Imitation Learning (GAIL) model.

Statement 13. An embodiment of the inventive concept includes a method, comprising:

determining a first output state for a first model given an input state for an autonomous vehicle simulation;

determining a second output state for a second model given the input state for the autonomous vehicle simulation; and

mixing the first output state and the second output state to produce a mixed output state,

wherein the mixed output state represents an actor in the autonomous vehicle simulation.

Statement 14. An embodiment of the inventive concept includes the method according to statement 13, wherein the actor includes one of a dynamic agent in the autonomous vehicle simulation or an autonomous vehicle in the autonomous vehicle simulation.

Statement 15. An embodiment of the inventive concept includes the method according to statement 13, wherein:

the method further comprises:
determining a first confidence level for the first output state for the first model; and
determining a second confidence level for the second output state for the second model; and

mixing the first output state and the second output state includes mixing the first output state and the second output state to produce the mixed output state responsive to the first confidence level and the second confidence level.

Statement 16. An embodiment of the inventive concept includes the method according to statement 15, wherein:

the first confidence level includes a first covariance matrix; and

the second confidence level includes a second covariance matrix.

Statement 17. An embodiment of the inventive concept includes the method according to statement 15, further comprising mixing the first confidence level and the second confidence level to produce a mixed confidence level.

Statement 18. An embodiment of the inventive concept includes the method according to statement 15, wherein mixing the first output state and the second output state to produce the mixed output state responsive to the first confidence level and the second confidence level includes:

determining a first weight and a second weight responsive to the first confidence level and the second confidence level; and

determining the mixed output state by weighting the first output state with the first weight and the second output state with the second weight.

Statement 19. An embodiment of the inventive concept includes the method according to statement 18, wherein:

the method further comprises:
determining at least a third output state for at least a third model given the input state for the autonomous vehicle simulation; and
determining at least a third confidence level for the at least a third output state for the at least a third model;

determining a first weight and a second weight responsive to the first confidence level and the second confidence level includes determining a first weight, a second weight, and at least a third weight responsive to the first confidence level, the second confidence level, and the at least a third confidence level; and

determining the mixed output state by weighting the first output state with the first weight and the second output state with the second weight includes determining the mixed output state by weighting the first output state with the first weight the second output state with the second weight, and the at least a third output state with the at least a third weight.

Statement 20. An embodiment of the inventive concept includes the method according to statement 13, further comprising determining the input state from at least one initial parameter.

Statement 21. An embodiment of the inventive concept includes the method according to statement 20, wherein determining the input state from at least one initial parameter includes:

determining a range of values for the at least one initial parameter responsive to a desired agent behavior; and

selecting a value in the range of values for the at least one initial parameter.

Statement 22. An embodiment of the inventive concept includes the method according to statement 13, further comprising using the mixed output state as a second input state to the first model and the second model.

Statement 23. An embodiment of the inventive concept includes the method according to statement 13, wherein:

the first model includes a model-based approach; and

the second model includes a deep data driven approach.

Statement 24. An embodiment of the inventive concept includes the method according to statement 13, wherein:

the model-based approach includes an Intelligent Driver Model (IDM); and

the deep data driven approach includes a Generative Adversarial Imitation Learning (GAIL) model.

Statement 25. An embodiment of the inventive concept includes an article, comprising a non-transitory storage medium, the non-transitory storage medium having stored thereon instructions that, when executed by a machine, result in:

determining a first output state for a first model given an input state for an autonomous vehicle simulation;

determining a second output state for a second model given the input state for the autonomous vehicle simulation; and

mixing the first output state and the second output state to produce a mixed output state,

wherein the mixed output state represents an actor in the autonomous vehicle simulation.

Statement 26. An embodiment of the inventive concept includes the article according to statement 25, wherein the actor includes one of a dynamic agent in the autonomous vehicle simulation or an autonomous vehicle in the autonomous vehicle simulation.

Statement 27. An embodiment of the inventive concept includes the article according to statement 25, wherein:

the method further comprises:
determining a first confidence level for the first output state for the first model; and
determining a second confidence level for the second output state for the second model; and

mixing the first output state and the second output state includes mixing the first output state and the second output state to produce the mixed output state responsive to the first confidence level and the second confidence level.

Statement 28. An embodiment of the inventive concept includes the article according to statement 27, wherein:

the first confidence level includes a first covariance matrix; and

the second confidence level includes a second covariance matrix.

Statement 29. An embodiment of the inventive concept includes the article according to statement 27, the non-transitory storage medium, having stored thereon further instructions that, when executed by the machine, result in mixing the first confidence level and the second confidence level to produce a mixed confidence level.

Statement 30. An embodiment of the inventive concept includes the article according to statement 27, wherein mixing the first output state and the second output state to produce the mixed output state responsive to the first confidence level and the second confidence level includes:

determining a first weight and a second weight responsive to the first confidence level and the second confidence level; and

determining the mixed output state by weighting the first output state with the first weight and the second output state with the second weight.

Statement 31. An embodiment of the inventive concept includes the article according to statement 30, wherein:

the method further comprises:
determining at least a third output state for at least a third model given the input state for the autonomous vehicle simulation; and
determining at least a third confidence level for the at least a third output state for the at least a third model;

determining a first weight and a second weight responsive to the first confidence level and the second confidence level includes determining a first weight, a second weight, and at least a third weight responsive to the first confidence level, the second confidence level, and the at least a third confidence level; and

determining the mixed output state by weighting the first output state with the first weight and the second output state with the second weight includes determining the mixed output state by weighting the first output state with the first weight the second output state with the second weight, and the at least a third output state with the at least a third weight.

Statement 32. An embodiment of the inventive concept includes the article according to statement 25, the non-transitory storage medium, having stored thereon further instructions that, when executed by the machine, result in determining the input state from at least one initial parameter.

Statement 33. An embodiment of the inventive concept includes the article according to statement 32, wherein determining the input state from at least one initial parameter includes:

determining a range of values for the at least one initial parameter responsive to a desired agent behavior; and

selecting a value in the range of values for the at least one initial parameter.

Statement 34. An embodiment of the inventive concept includes the article according to statement 25, the non-transitory storage medium, having stored thereon further instructions that, when executed by the machine, result in using the mixed output state as a second input state to the first model and the second model.

Statement 35. An embodiment of the inventive concept includes the article according to statement 25, wherein:

the first model includes a model-based approach; and

the second model includes a deep data driven approach.

Statement 36. An embodiment of the inventive concept includes the article according to statement 25, wherein:

the model-based approach includes an Intelligent Driver Model (IDM); and

the deep data driven approach includes a Generative Adversarial Imitation Learning (GAIL) model.

Consequently, in view of the wide variety of permutations to the embodiments described herein, this detailed description and accompanying material is intended to be illustrative only, and should not be taken as limiting the scope of the inventive concept. What is claimed as the inventive concept, therefore, is all such modifications as may come within the scope and spirit of the following claims and equivalents thereto.

What is claimed is:

1. A system, comprising:
a processor executing at least a first model to produce a first output state for an input state for an autonomous vehicle simulation and a second model to produce a second output state for the input state for the autonomous vehicle simulation; and
a state mixer to mix the first output state and the second output state to produce a mixed output state,
wherein the mixed output state represents an actor in the autonomous vehicle simulation.

2. The system according to claim 1, wherein the actor includes one of a dynamic agent in the autonomous vehicle simulation or an autonomous vehicle in the autonomous vehicle simulation.

3. The system according to claim 1, wherein:
the processor is operative to produce a first confidence level for the first output state for the first model and a second confidence level for the second output state for the second model; and
the state mixer is operative to mix the first output state and the second output state to produce a mixed output state responsive to the first confidence level and the second confidence level.

4. The system according to claim 3, wherein:
the state determiner includes a weight determiner to determine a first weight and a second weight responsive to the first confidence level and the second confidence level; and
the state mixer is operative to weight the first output state with the first weight and the second output state with the second weight to produce the mixed output state.

5. The system according to claim 4, wherein:
the processor is operative to execute at least a third model to produce a third output state for the input state for an autonomous vehicle simulation and a third confidence level for the third output state for the third model;
the weight determiner is operative to determine the first weight, the second weight, and a third weight responsive to the first confidence level, the second confidence level, and the third confidence level; and
the state mixer is operative to weight the first output state with the first weight, the second output state with the second weight, and the third output state with the third weight to produce the mixed output state.

6. The system according to claim 1, further comprising storage for at least one initial parameter.

7. The system according to claim 6, wherein the storage for at least one initial parameter includes storage for at least one range of values for the at least one parameter responsive to a desired agent behavior.

8. The system according to claim 1, wherein:
the first model includes a model-based approach; and
the second model includes a deep data driven approach.

9. The system according to claim 8, wherein:
the model-based approach includes an Intelligent Driver Model (IDM); and
the deep data driven approach includes a Generative Adversarial Imitation Learning (GAIL) model.

10. A method, comprising:
determining a first output state for a first model given an input state for an autonomous vehicle simulation;
determining a second output state for a second model given the input state for the autonomous vehicle simulation; and
mixing the first output state and the second output state to produce a mixed output state,
wherein the mixed output state represents an actor in the autonomous vehicle simulation.

11. The method according to claim 10, wherein:
the method further comprises:
determining a first confidence level for the first output state for the first model; and
determining a second confidence level for the second output state for the second model; and
mixing the first output state and the second output state includes mixing the first output state and the second output state to produce the mixed output state responsive to the first confidence level and the second confidence level.

12. The method according to claim 11, wherein mixing the first output state and the second output state to produce the mixed output state responsive to the first confidence level and the second confidence level includes:
determining a first weight and a second weight responsive to the first confidence level and the second confidence level; and
determining the mixed output state by weighting the first output state with the first weight and the second output state with the second weight.

13. The method according to claim 12, wherein:
the method further comprises:
determining at least a third output state for at least a third model given the input state for the autonomous vehicle simulation; and
determining at least a third confidence level for the at least a third output state for the at least a third model;
determining a first weight and a second weight responsive to the first confidence level and the second confidence level includes determining a first weight, a second weight, and at least a third weight responsive to the first confidence level, the second confidence level, and the at least a third confidence level; and
determining the mixed output state by weighting the first output state with the first weight and the second output state with the second weight includes determining the mixed output state by weighting the first output state with the first weight the second output state with the second weight, and the at least a third output state with the at least a third weight.

14. The method according to claim 10, further comprising determining the input state from at least one initial parameter.

15. The method according to claim 14, wherein determining the input state from at least one initial parameter includes:
determining a range of values for the at least one initial parameter responsive to a desired agent behavior; and
selecting a value in the range of values for the at least one initial parameter.

16. The method according to claim 10, further comprising using the mixed output state as a second input state to the first model and the second model.

17. The method according to claim 10, wherein:
the first model includes a model-based approach; and
the second model includes a deep data driven approach.

18. The method according to claim 10, wherein:
the model-based approach includes an Intelligent Driver Model (IDM); and
the deep data driven approach includes a Generative Adversarial Imitation Learning (GAIL) model.

19. An article, comprising a non-transitory storage medium, the non-transitory storage medium having stored thereon instructions that, when executed by a machine, result in:
determining a first output state for a first model given an input state for an autonomous vehicle simulation;
determining a second output state for a second model given the input state for the autonomous vehicle simulation; and
mixing the first output state and the second output state to produce a mixed output state,
wherein the mixed output state represents an actor in the autonomous vehicle simulation.

20. The article according to claim 19, wherein the actor includes one of a dynamic agent in the autonomous vehicle simulation or an autonomous vehicle in the autonomous vehicle simulation.
